(19) United States
(12) Patent Application Publication
(10) Pub. No.: US 2006/0292975 A1
(43) Pub. Date: Dec. 28, 2006

(54) Heat dissipating module and casing thereof

(75) Inventors: Chia-Ching Lin, Taoyuan Hsien (TW); Peng-Chu Tao, Taoyuan Hsien (TW); Te-Tsai Chuang, Taoyuan Hsien (TW); Wen-Shi Huang, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/357,069

(22) Filed: Feb. 21, 2006

(30) Foreign Application Priority Data
Jun. 28, 2005 (TW) 094121530

(51) Int. Cl. H05K 5/00

(52) U.S. Cl. 454/184

(57) ABSTRACT

A heat dissipating module includes a casing and at least one fan. The casing includes a first casing body having at lease one air-guiding portion and at least one porous area. The air-guiding portion and the porous area are integrally formed as a monolithic unit. The fans are disposed within the casing and each fan is disposed with respect to each air-guiding portion, respectively. Each of the air-guiding portions has a first end connected to the first casing body, and a second end disposed around the porous area. Each of the porous areas has a plurality of holes for allowing air to enter the fans inside the casing along the air-guiding portion.

This non-provisional application claims priority under U.S.C.§ 119(a) on patent application no(s). 094121530, filed in Taiwan, Republic of China on Jun. 28, 2005, the entire contents of which are hereby incorporated by reference.

### BACKGROUND OF THE INVENTION

1. Field of Invention

The present invention relates to a heat dissipating module, and more particular to a heat dissipating module with an improved casing.

2. Related Art

Conventionally, in order to avoid dust contamination from the atmosphere, most electronic products enclose electronic devices inside a casing. However, the electronic devices will generate lots of heat during their operations, the devices are likely to be damaged and decreases the lifetime continuously under such a high temperature state. A heat dissipating module is thus provided to quickly dissipate the heat generated from the electronic devices out to outside for preventing the electronic devices from failure.

As shown in FIG. 1, a conventional heat dissipating module 10 includes a casing 11, an inlet ring 12 and four fans 13. The casing 11 is consisted of an iron cover 111 and an iron casing 112. The iron cover 111 has a plurality of holes and forms an inlet area 113. The inlet ring 12 is fixed on the iron cover 111 where is close to the inlet area 113 by soldering so as to guide the airflow and prevent the airflow from leaking out between the inlet area 113 and the fan 13, which results in a smaller airflow. Each of the fans 13 is disposed on one side of the inlet ring 12, and the iron casing 112 and the iron cover 111 are assembled via several screws 14.

As shown in FIGS. 1 and 2, the iron cover 111 and the inlet ring 12 are separately manufactured by metal molding formation, and then are combined by soldering, riveting or other equivalent connecting methods. However, before performing the soldering procedure, it is necessary to align the inlet ring 12 with the iron cover 111. In order to achieve accurate alignment between the inlet ring 12 and the iron cover 111 in the prior art, a plurality of positioning holes 114 are punched around the iron cover 111, so that a plurality of grooves 121 on the inlet ring 12 may align with the positioning holes 114 to ensure the inlet ring 12 completely surrounding the inlet area 113 before soldering.

Aside from the facts that the positioning procedure to solder the inlet ring 12 onto the iron cover 111 is complicated and hard to achieve, the soldering procedure further results in black soldering points (indicated by * in the drawing) on the surface of the iron cover 111. For a better appearance, an electroplating or painting procedure is performed to remove the soldering points. Moreover, for the operation of soldering and electroplating procedures, the materials of the iron cover 111 and the inlet ring 12 have to be chosen as appropriate metals such as the steel plate cold-rolled commercial (SPCC). The available materials for the iron cover 111 and the inlet ring 12 are thus limited.

Furthermore, due to the tapered construction of the inlet ring 12, the space around the connection of the inlet ring 12 and the iron cover 111 becomes a blind angle, where dust is easily accumulated.

It is thus imperative to provide a heat dissipating module and a casing thereof to solve the problems of alignment and ugly soldering points when mounting the inlet ring onto the iron cover by soldering and the problem that dusts tend to accumulate between the inlet ring and the iron cover.

### SUMMARY OF THE INVENTION

In view of the foregoing, the present invention provides a heat dissipating module and a casing thereof to solve above-mentioned problems when the inlet ring and the iron cover are connected by soldering in the prior art.

To achieve the above, a casing of a heat dissipating module according to the present invention includes a first casing body having at least one air-guiding portion and at least one porous area. The air-guiding portion has a first end connected to the first casing body, and a second end disposed around the porous area. The porous area has a plurality of holes.

To achieve the above, a heat dissipating module according to the present invention includes a casing and at least one fan. The casing includes a first casing body having at least one air-guiding portion and at least one porous area. The fan is disposed within the casing and is disposed with respect to the air-guiding portion. The air-guiding portion has a first end connected to the first casing body, and a second end disposed around the porous area. The porous area has a plurality of holes.

The air-guiding portions and the porous areas are integrally formed as a single unit by punching or by injection molding. The air-guiding portions and the porous areas are integrally formed with the first casing body as a single unit by punching or by injection molding. The diameter of the first end of the air-guiding portion is greater than that of the second end. The casing further includes a second casing body connected with the first casing body to form an accommodating space for receiving the fan therein. The second casing body is connected with the first casing body by a plurality of screwing elements or a plurality of locking elements. Alternatively, the second casing body and the first casing body are connected by welding, riveting, screw fastening, adhesive bonding, embedding, clipping or locking. The first casing body and the second casing body are made of metal or plastic.

As mentioned above, because the air-guiding portions and the porous areas are integrally formed with the first casing body, a heat dissipating module and a casing thereof as a single unit according to the present invention do not involve soldering or other connecting procedures to combine the air-guiding portions and the porous areas. Comparing with the prior art, the present invention can skip further machining processes for the groove and positioning points for the alignment of the air-guiding portions and the porous areas. It can also skip the post-machining processes of electroplating or painting for removing the soldering points. Therefore, the present invention simplifies the manufacturing process and lowers the production cost. Since no soldering and electroplating processes are needed, the material selection in the casing of the heat dissipating module is more flexible. Moreover, since the air-guiding portion and the porous area are integrally formed with the first casing body as a single unit, there is no blind angle formed between the air-guiding portion and the first casing body. As the results, the present invention prevents problems of dust accumulation between the air-guiding portion and the first casing body in the prior art.

### BRIEF DESCRIPTION OF THE DRAWINGS

The present invention will become more fully understood from the detailed description given herein below illustration only, and thus are not limitative of the present invention, and wherein:

FIG. 1 is a schematic view showing a conventional heat dissipating module;

FIG. 2 is a schematic view showing a conventional casing of the heat dissipating module in FIG. 1;

FIG. 3 is a schematic view showing the casing of a heat dissipating module according to a preferred embodiment of the present invention;

FIG. 4 is a schematic view showing the first casing body in FIG. 3;

FIG. 5 is a cross-sectional view along the C-C′ line in FIG. 4, which shows the air-guiding portion and the porous area; and

FIG. 6 is a schematic view showing a heat dissipating module according to a preferred embodiment of the present invention.

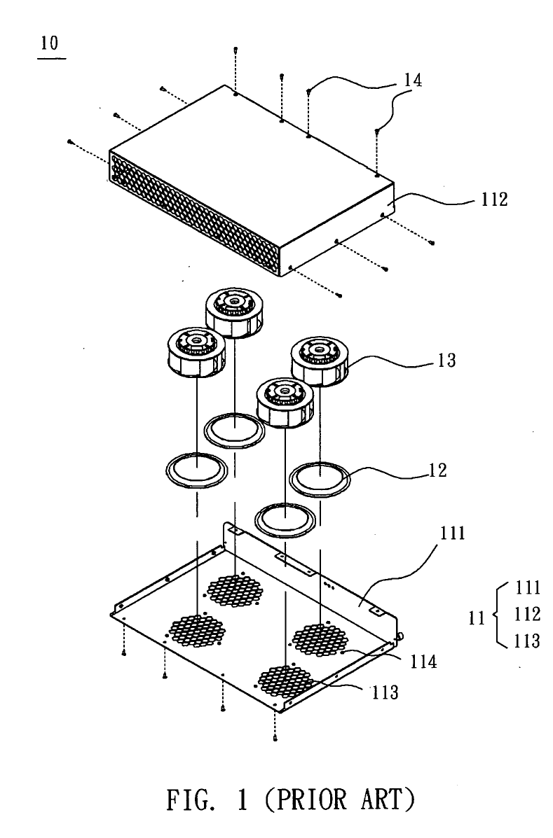

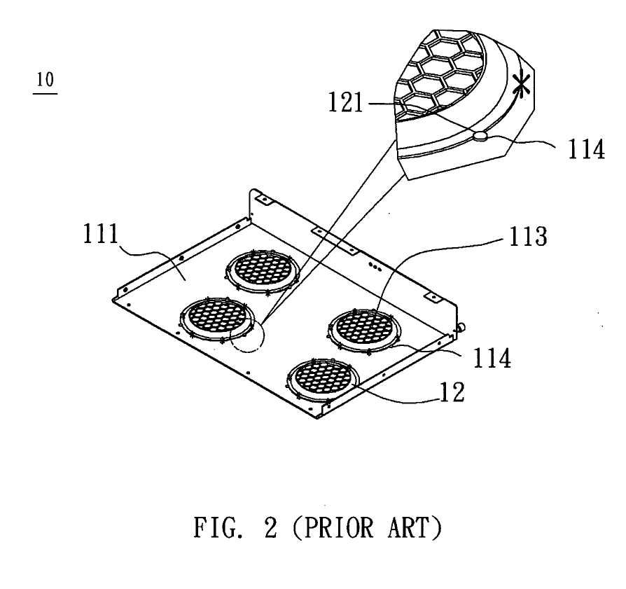

### DETAILED DESCRIPTION OF THE INVENTION

The present invention will be apparent from the following detailed description, which proceeds with reference to the accompanying drawings, wherein the same references relate to the same elements.

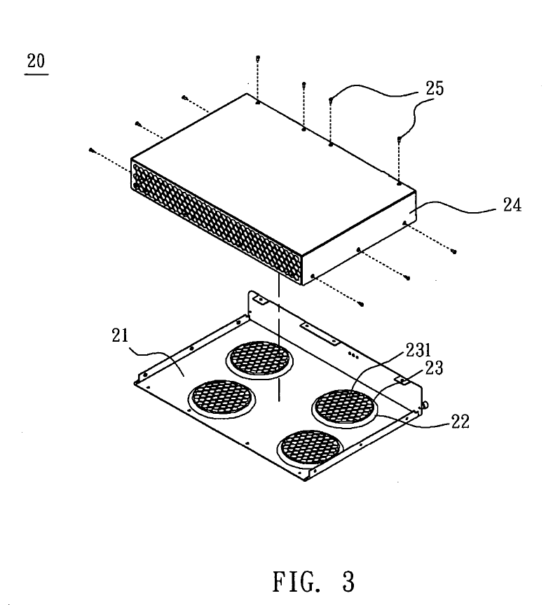

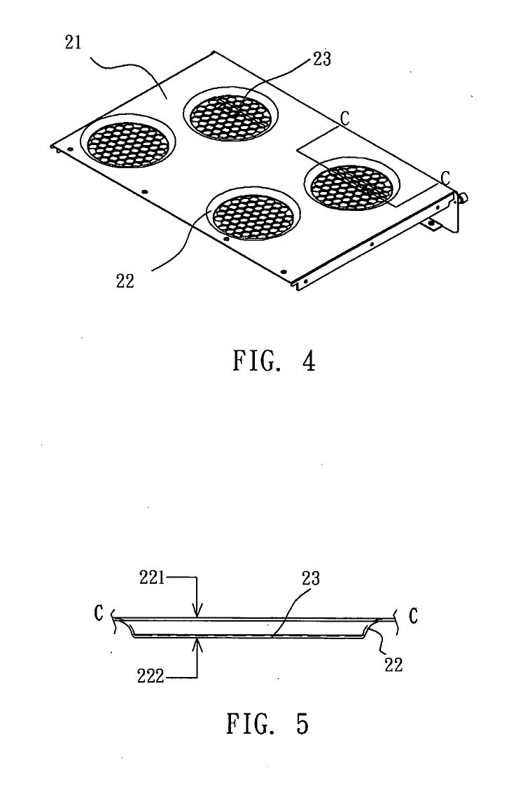

FIGS. 3, 4 and 5 show a casing of a heat dissipating module according to a preferred embodiment of the present invention. As shown in FIG. 3, a casing 20 of a heat dissipating module includes a first casing body 21 and a second casing body 24. Please note that the first casing body 21 in FIG. 4 is shown in the opposite direction to the first casing body 21 in FIG. 3. That is, turning the first casing body 21 in FIG. 3 in the opposite direction renders the first casing body 21 in FIG. 4.

The second casing body 24 is connected with the first casing body 21 to form an accommodating space for receiving at least one fan therein. The second casing body 24 is connected with the first casing body 21 by a plurality of screwing elements 25 or a plurality of locking elements. Alternatively, the second casing body 24 and the first casing body 21 are connected by welding, riveting, screw fastening, adhesive bonding, embedding, clipping or locking.

The first casing body 21 has at least one air-guiding portion 22 and at least one porous area 23. As shown in FIG. 5, The air-guiding portion 22 is preferably an inlet ring and has a first end 221 and a second end 222 on opposite side. The first end 221 of the air-guiding portion 22 is directly connected to the first casing body 21, and the second end 222 of the air-guiding portion 22 is disposed around the porous area 23. The diameter of the first end 221 is greater than that of the second end 222. The air-guiding portion 22 and the porous area 23 are integrally formed as a monolithic unit. The porous area 23 is preferably a fan guard with a plurality of holes 231 for allowing air to enter the casing 20 through the porous area 23.

In a practical manufacturing, the porous areas 23 are formed on the first casing body 21 by punching or by injection molding, and then the air-guiding portions 22 are formed on and disposed around the porous area 23 by another punching procedure, and vice versa. Alternatively, the air-guiding portions 22 and the porous areas 23 can be simultaneously formed on the first casing body 21 by one single punching procedure, so that they are integrally formed on the first casing body 21 as a single unit.

As shown in FIGS. 4 and 5, each of the air-guiding portions 22 is recessed inwardly and integrally formed with the porous area 23 and the first casing body 21 as a single unit. When the punching or injection molding procedure is performing, the air-guiding portion 22 can be formed on the first casing body 21 in a predetermined angle, so as to avoid dusts from accumulating between the air-guiding portion 22 and the first casing body 21. Further, since no soldering or other connecting process is involved when the air-guiding portion 22 and the porous area 23 are connected, the material selection in the casing 20 of the heat dissipating module has more flexibly, e.g. the casing 20 is preferably made of metal or plastic. That is, the first casing body 21 may be an iron cover or a plastic casing cover, and the second casing body 24 may be an iron casing or a plastic casing.

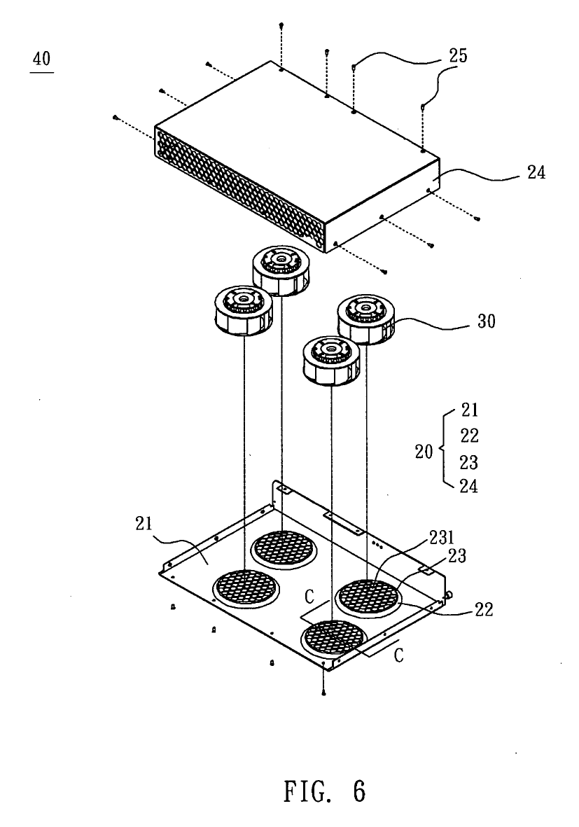

As shown in FIG. 6, a heat dissipating module 40 of a preferred embodiment of the present invention includes a casing 20 and at least one fan 30. In this embodiment, the heat dissipating module 40 is disposed in a large machine to help the electronic devices therein dissipating heat.

The casing 20 has a first casing body 21 and a second casing body 24. The second casing body 24 is connected with the first casing body 21 to form an accommodating space for receiving the fan 30 therein. The second casing body 24 is connected with the first casing body 21 by a plurality of screwing elements 25 such as screws or a plurality of locking elements such as buckles. Alternatively, the second casing body 24 and the first casing body 21 are connected by welding, riveting, screw fastening, adhesive bonding, embedding, clipping or locking. In this embodiment, the air-guiding portions 22 and the porous areas 23 of the first casing body 21 have the same constructions and functions as those in the previous embodiment. Therefore, they will not be further described herein.

In this embodiment, four fans 30 are disposed within the casing 20. Each of the fans 30 is disposed with respect to one of the air-guiding portions 22. The air-guiding portion 22 is preferably an inlet ring, of which one side (first end) is directly connected to the first casing body 21 and the other side (second end) is disposed around the porous area 23. Each of the porous areas 23 has a plurality of holes 231. In this embodiment, the fan 30 faces to the porous areas 23, and air from outside is through the porous area 23 and is guided by the air-guiding portion 22 to enter the fans 30. Afterwards, the fan 30 sends the airflow to dissipate the heat of the electronic devices. Although the fans 30 adopted in this embodiment are not limitative to centrifugal fans, one may also adopt axial fans. Also, the number of fans is not limited thereto.

In summary, because the air-guiding portions and the porous areas are integrally formed with the first casing body, a heat dissipating module and a casing thereof as a single unit according to the present invention do not involve soldering or other connecting procedures to combine the air-guiding portions and the porous areas. Comparing with the prior art, the present invention can skip further machining processes for the groove and positioning points for the alignment of the air-guiding portion and the porous area. It can also skip the post-machining processes of electroplating or painting for removing the soldering points. Therefore, the present invention simplifies the manufacturing process and lowers the production cost. Since no soldering and electroplating processes are needed, the material selection in the casing of the heat dissipating module is more flexible. Moreover, since the air-guiding portion and the porous area are integrally formed with the first casing body as a single unit, there is no blind angle formed between the air-guiding portion and the first casing body. As the results, the present invention prevents problems of dust accumulation between the air-guiding portion and the first casing body in the prior art.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A casing of a heat dissipating module, comprising a first casing body
having at least one air-guiding portion and at least one porous area, the air-guiding portion and the porous area being integrally formed as a monolithic unit;
wherein each of the air-guiding portions has a first end connected to the first casing body, and a second end disposed around the porous area, and
each of the porous area has a plurality of holes.

2. The casing according to claim 1, wherein the air-guiding portions and the porous areas are integrally formed by punching or by injection molding.

3. The casing according to claim 1, wherein the air-guiding portions and the porous areas are integrally formed with the first casing body as a single unit.

4. The casing according to claim 3, wherein the air-guiding portions and the porous areas are integrally formed with the first casing body as a single unit by punching or by injection molding.

5. The casing according to claim 1, wherein a diameter of the first end of the air-guiding portion is greater than that of the second end of the air-guiding portion.

6. The casing according to claim 1, further comprising a second casing body connected with the first casing body to form an accommodating space.

7. The casing according to claim 6, wherein the second casing body is connected with the first casing body by a plurality of screwing elements or a plurality of locking elements.

8. The casing according to claim 6, wherein the second casing body and the first casing body are connected by welding, riveting, screw fastening, adhesive bonding, embedding, clipping or locking.

9. The casing according to claim 6, wherein the first casing body and the second casing body comprise metal or plastic.

10. A heat dissipating module, comprising:
a casing comprising a first casing body, which has at least one air-guiding portion and at least one porous area, the air-guiding portion and the porous area being integrally formed as a monolithic unit; and
at least one fan, disposed within the casing and each of the fans being disposed with respect to each of the air-guiding portions.

11. The heat dissipating module according to claim 10, wherein each of the
air-guiding portions has a first end connected to the first casing body, and
a second end disposed around the porous area, and each of the porous area has a plurality of holes.

12. The heat dissipating module according to claim 10, wherein the air-guiding portions and the porous areas are integrally formed as a single unit by punching or by injection molding.

13. The heat dissipating module according to claim 10, wherein the air-guiding portions and the porous areas are integrally formed with the first casing body as a single unit.

14. The heat dissipating module according to claim 13, wherein the air-guiding portions and the porous areas are integrally formed with the first casing body as a single unit by punching or by injection molding.

15. The heat dissipating module according to claim 10, wherein a diameter of the first end of the air-guiding portion is greater than that of the second end of the air-guiding portion.

16. The heat dissipating module according to claim 14, wherein the first casing body comprises metal or plastic.

17. The heat dissipating module according to claim 10, wherein the casing further comprising a second casing body connected with the first casing body to form an accommodating space for receiving the fan.

18. The heat dissipating module according to claim 17, wherein the second casing body is connected with the first casing body by a plurality of screwing elements or a plurality of locking elements.

19. The heat dissipating module according to claim 17, wherein the second casing body and the first casing body are connected by welding, riveting, screw fastening, adhesive bonding, embedding, clipping or locking.

20. The heat dissipating module according to claim 17, wherein the first casing body and the second casing body comprise metal or plastic.
